(19) United States
(12) Patent Application Publication
(10) Pub. No.: US 2006/0163604 A1
(43) Pub. Date: Jul. 27, 2006

(54) Gallium nitride-based light emitting device having light emitting diode for protecting electrostatic discharge, and melthod for manufacturing the same

(75) Inventors: Hyoun Soo Shin, Seoul (KR); Hyun Kyung Kim, Suwon (KR); In Joon Pyeon, Seoul (KR); Chang Wan Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/244,084

(22) Filed: Oct. 6, 2005

(30) Foreign Application Priority Data
Jan. 27, 2005 (KR) 10-2005-7587

(51) Int. Cl. H01L 21/00; H01L 33/00

(52) U.S. Cl. 257/103; 438/46; 257/96

(57) ABSTRACT

A gallium nitride-based light emitting device, and a method for manufacturing the same are provided. The light emitting device comprises a substrate; a main GaN-based LED including a first p-side electrode and a first n-side electrode, the main GaN-based LED formed in a first region on the substrate; and an ESD protecting GaN-based LED including a second p-side electrode and a second n-side electrode, the ESD protecting GaN-based LED formed in a second region on the substrate. The first region is separated from the second region by a device isolation region. The first p-side and n-side electrodes are electrically connected to the second n-side and p-side electrodes, respectively.

### RELATED APPLICATION

The present invention is based on, and claims priority from, Korean Application Number 2005-7587, filed Jan. 27, 2005, the disclosure of which is incorporated by reference herein in its entirety.

### BACKGROUND OF THE INVENTION

1. Field of the Invention

The present invention generally relates to a gallium nitride-based light emitting device and a method for manufacturing the same, and, more particularly, to a gallium nitride-based light emitting device, designed to have an enhanced resistance to reverse electrostatic discharge (ESD), and a method for manufacturing the same.

2. Description of the Related Art

Generally, a conventional gallium nitride-based light emitting device comprises a buffer layer, an n-type GaN-based clad layer, an active layer, and a p-type GaN-based clad layer sequentially stacked on a dielectric sapphire substrate. Additionally, a transparent electrode and a p-side electrode are sequentially formed on the p-type GaN-based clad layer, and an n-side electrode is formed on a portion of the n-type GaN-based clad layer exposed by mesa etching. In such a gallium nitride-based light emitting device, holes from the p-side electrode and electrons from the n-side electrode are coupled to emit light corresponding to the energy band gap of a composition of the active layer.

Although the gallium nitride-based light emitting device has a significant energy band gap, it is generally vulnerable to ESD. The gallium nitride-based light emitting device based on a material having the formula AlₓGa_{y}In_{1-x-y}N (0≦x≦1, 0≦y≦1, 0≦x+y≦1) has a breakdown voltage of about 1 to 3 kV against forward ESD, and a breakdown voltage of about 100 V to 1 kV against reverse ESD. As such, the gallium nitride-based light emitting device is more vulnerable to the reverse ESD than the forward ESD. Thus, when a large reverse ESD voltage is applied in a pulse shape to the gallium nitride-based light emitting device, the light emitting device can be damaged. Such a reverse ESD damages reliability of the gallium nitride-based light emitting device as well as causing a sharp reduction in life span thereof.

In order to solve the above mentioned problem, several approaches for enhancing resistance to ESD of the gallium nitride-based light emitting device have been suggested. For example, a gallium nitride-based light emitting diode (referred to hereinafter as “LED”) of flip-chip structure is connected in parallel to a Si-based Zener diode so as to protect the light emitting device from ESD. However, in this method, an additional Zener diode must be purchased, and then assembled thereto by bonding, thereby significantly increasing material costs and manufacturing costs as well as restricting miniaturization of the device. As another method, U.S. Pat. No. 6,593,597 discloses technology for protecting the light emitting device from ESD by integrating an LED and a Schottky diode on the same substrate and connecting them in parallel.

FIG. 1a is a cross-sectional view illustrating a conventional gallium nitride light emitting device having a Schottky diode connected in parallel as described above, and FIG. 1b is an equivalent circuit diagram of FIG. 1a. Referring to FIG. 1a, LED structure of the conventional light emitting device comprises a first nucleus generation layer 12a, a first conductive buffer layer 14a, a lower confinement layer 16, an active layer 18, an upper confinement layer 20, a contact layer 22, a transparent electrode 24, and an n-side electrode 26 sequentially formed on a transparent substrate 11. Separated from the LED structure, a second nucleus generation layer 12b and a second conductive buffer layer 14b are formed on the transparent substrate 11, and a Schottky contact electrode 28 and an ohmic contact electrode 30 are formed on the second conductive buffer layer 14b, thereby forming a Schottky diode.

The transparent electrode 24 of the LED structure is connected to the ohmic contact electrode 30, and the n-side electrode 26 of the LED structure is connected to the Schottky contact electrode 28. As a result, as shown in FIG. 1b, the light emitting device has a structure wherein the LED is connected to the Schottky diode in parallel. In the light emitting device constructed as described above, when a high reverse voltage, for example, a reverse ESD voltage, is instantaneously applied thereto, the high voltage can be discharged through the Schottky diode. Accordingly, most of current flows through the Schottky diode instead of the LED, thereby reducing damage of the light emitting device.

However, the method of protecting the light emitting device from ESD using the Schottky diode has a drawback in that it entails a complicated manufacturing process. In other words, not only a region for LED must be divided from a region for the Schottky diode, but also it is necessary to deposit an additional electrode material in ohmic contact with an electrode material constituting the Schottky diode on the second conductive buffer layer 14b composed of n-type GaN-based materials. In particular, there are problems of limitation of the kind of metallic material forming Schottky contact with the n-type GaN-based materials, and of possibility of change in contact properties of semiconductor-metal in following processes, such as heat treatment.

### SUMMARY OF THE INVENTION

The present invention has been made in view of the above problems, and it is an object of the present invention to provide a gallium nitride-based light emitting device, which has an enhanced resistance to reverse ESD.

It is another object of the present invention to provide a method for manufacturing a gallium nitride-based light emitting device, which can simplify a process and enhance resistance to reverse ESD in LED.

In accordance with one aspect of the present invention, the above and other objects can be accomplished by the provision of a gallium nitride-based light emitting device comprising; a substrate; a main GaN-based LED including a first p-side electrode and a first n-side electrode, the main GaN-based LED formed in a first region on the substrate; and an ESD protecting GaN-based LED including a second p-side electrode and a second n-side electrode, the ESD protecting GaN-based LED formed in a second region on the substrate, wherein the first region is separated from the second region by a device isolation region, and the first p-side and n-side electrodes are electrically connected to the second n-side and p-side electrodes, respectively.

The main GaN-based LED may comprise a first mesa structure including a first n-type GaN-based clad layer, a first active layer and a first p-type GaN-based clad layer sequentially formed on the substrate, the first n-type GaN-based clad layer having a partially exposed region; a first p-side electrode formed on the first p-type GaN-based clad layer; and a first n-side electrode formed on the exposed region of the first n-type GaN-based clad layer. The ESD protecting GaN-based LED may comprise a second mesa structure including a second n-type GaN-based clad layer, a second active layer and a second p-type GaN-based clad layer sequentially formed on the substrate, the second n-type GaN-based clad layer having a partially exposed region; a second p-side electrode formed on the second p-type GaN-based clad layer; and a second n-side electrode formed on the exposed region of the second n-type GaN-based clad layer.

The main GaN-based LED may further comprise a transparent electrode between the first p-type GaN-based clad layer and the first p-side electrode. The ESD protecting GaN-based LED may further comprise a transparent electrode between the second p-type GaN-based clad layer and the second p-side electrode. In this case, a passivation layer can be further provided on the first and second mesa structure and the transparent electrode to open the first and second p-side electrodes and the first and second n-side electrodes. The passivation layer acts to protect the LED.

The light emitting device of the invention may further comprise forming a wire layer for connecting the first p-side electrode to the second n-side electrode on the passivation layer. Preferably, the first and second p-side electrodes, and the first and second n-side electrodes are made of the same material. Additionally, the wire layer is made of the same material as that of the first and second p-side electrodes, and the first and second n-side electrodes. For example, the wire layer, the first and second p-side electrodes, and the first and second n-side electrodes comprise a Cr/Au layer.

Preferably, the ESD protecting GaN-based LED has ⅙ to ½ the size of the main GaN-based LED. If the ESD protecting GaN-based LED is significantly large, the overall size of the device is increased, thereby increasing manufacturing costs. If the ESD protecting GaN-based LED is significantly small, protection efficiency against reverse ESD voltage is lowered.

In accordance with another aspect of the invention, there is provided a method for manufacturing a gallium nitride-based light emitting device, comprising the steps of: sequentially forming an n-type GaN-based clad layer, an active layer and a p-type GaN-based clad layer on a substrate; exposing a portion of the n-type GaN-based clad layer by etching some portions of the p-type GaN-based clad layer, active layer and n-type GaN-based clad layer; forming a first mesa structure and a second mesa structure separated from each other by partially etching the exposed portion of the n-type GaN-based clad layer; forming n-side electrodes on the exposed n-type GaN-based clad layer of the first and second mesa structures, respectively; and forming p-side electrodes on the p-type GaN-based clad layer of the first and second mesa structures, respectively. The n-side electrodes and p-side electrodes may be formed at the same time.

Preferably, the first mesa structure is larger than the second mesa structure. The first and second mesa structures are contained in the main GaN-based LED and the ESD protecting GaN-based LED, respectively. Preferably, the size of the second mesa structure is ⅙ to ½ the size of the first mesa structure.

The method of the invention may further comprise forming a transparent electrode on the p-type GaN-based clad layer of the first mesa structure before forming the n-side electrode. Additionally, the method of the invention may further comprise forming another transparent electrode on the p-type GaN-based clad layer of the second mesa structure. In this case, the transparent electrode of the first mesa structure, and the transparent electrode of the second mesa structure may be formed at the same time. The method of the invention may further comprise forming a passivation layer on the first and second mesa structures and the transparent electrode between the steps of forming the n-side electrodes and the transparent electrode.

The method of the invention may further comprise forming a wire layer for connecting the p-side electrode of the first mesa structure to the n-side electrode of the second mesa structure when forming the n-side electrodes.

According to the present invention, two GaN-based LEDs (that is, the main GaN-based LED and the ESD protecting GaN-based LED) are separately formed on a single substrate, thereby allowing the GaN-based light emitting device having an enhanced resistance to reverse ESD to be more easily manufactured. In the present invention, an additional electrode forming process is not required to form Schottky contact. Moreover, since the existing material for the electrodes of the GaN-based LED is used, the process becomes very simple. Additionally, as described below, during the step of forming the n-side electrode, the wire layer may be formed for connecting the p-side electrode of the main LED to the n-side electrode of the ESD protecting LED, thereby reducing the number of wire-bonding portions while enabling detection of leakage current of the main LED prior to wire bonding.

### BRIEF DESCRIPTION OF THE DRAWINGS

The above and other objects, features and other advantages of the present invention will be more clearly understood from the following detailed description taken in conjunction with the accompanying drawings, in which:

FIG. 1a is a cross-sectional view illustrating a conventional gallium nitride-based light emitting device having a Schottky diode connected in parallel;

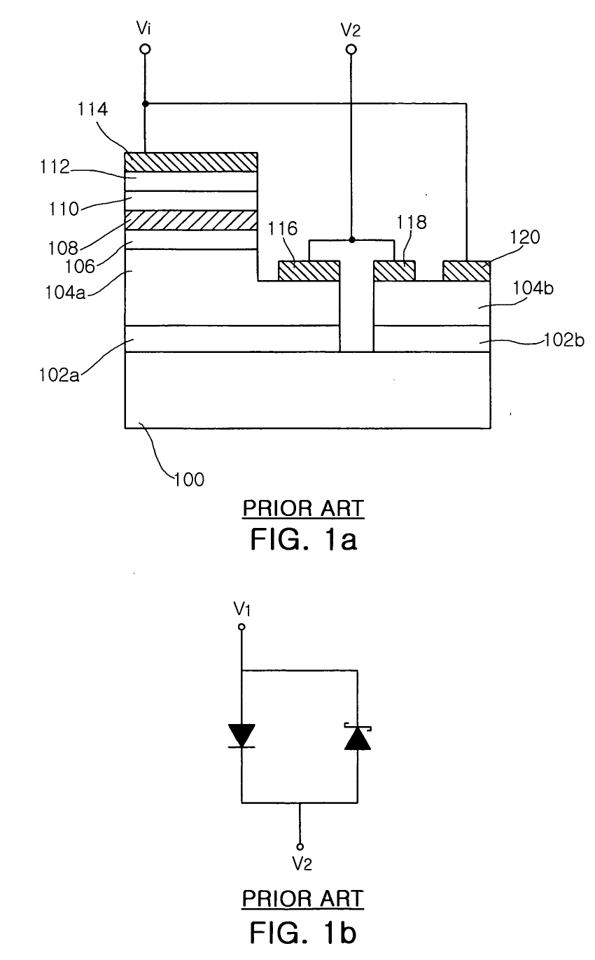

FIG. 1b is an equivalent circuit diagram of FIG. 1;

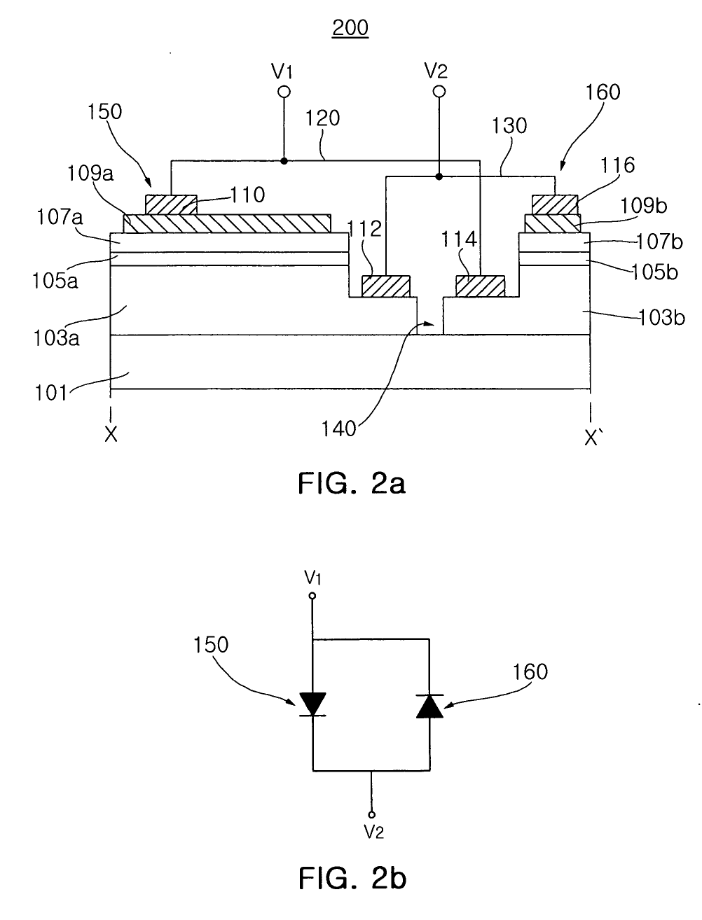

FIG. 2a is a cross-sectional view illustrating a gallium nitride-based light emitting device according to one embodiment of the present invention;

FIG. 2b is an equivalent circuit diagram of FIG. 2;

FIG. 2b is a plan view illustrating the gallium nitride-based light emitting device according to the embodiment; and

FIGS. 3 to 8 are cross-sectional views illustrating a method for manufacturing a gallium nitride-based light emitting device according to one embodiment of the invention.

### DESCRIPTION OF THE PREFERRED EMBODIMENTS

Preferred embodiments will now be described in detail with reference to the accompanying drawings. It should be noted that the embodiments of the invention can be modified in various shapes, and that the present invention is not limited to the embodiments described herein. The embodiments of the invention are described so as to enable those having an ordinary knowledge in the art to have a perfect understanding of the invention. Accordingly, shape and size of components of the invention are enlarged in the drawings for clear description of the invention. Like components are indicated by the same reference numerals throughout the drawings.

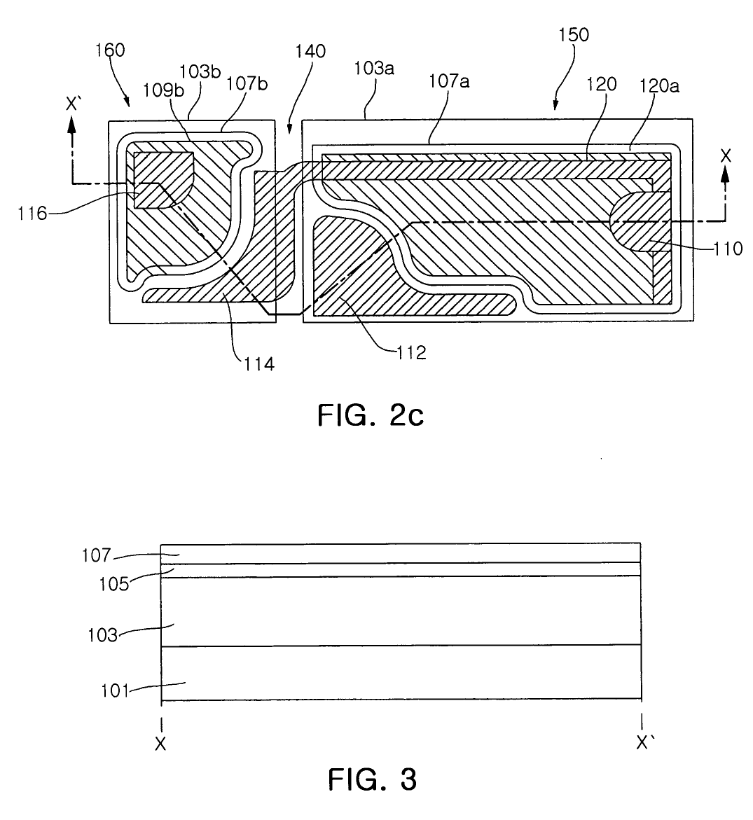

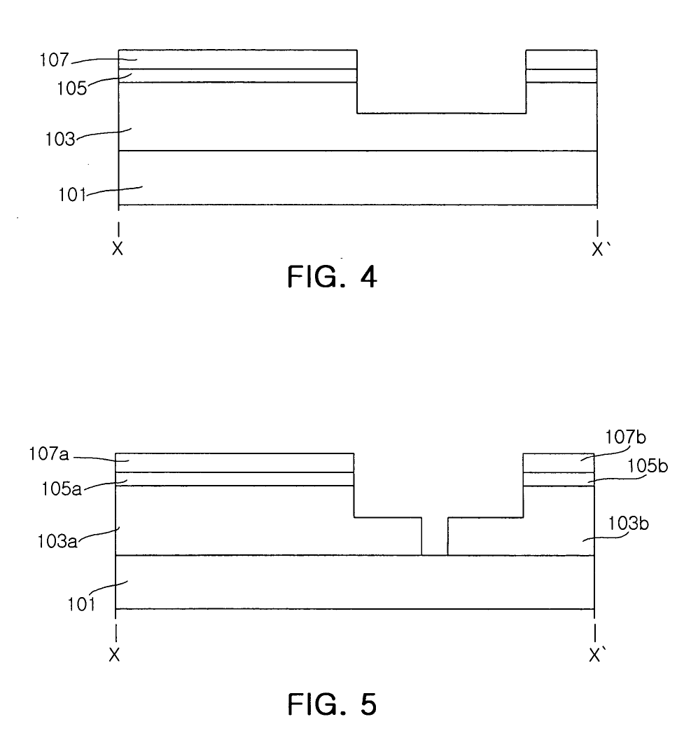

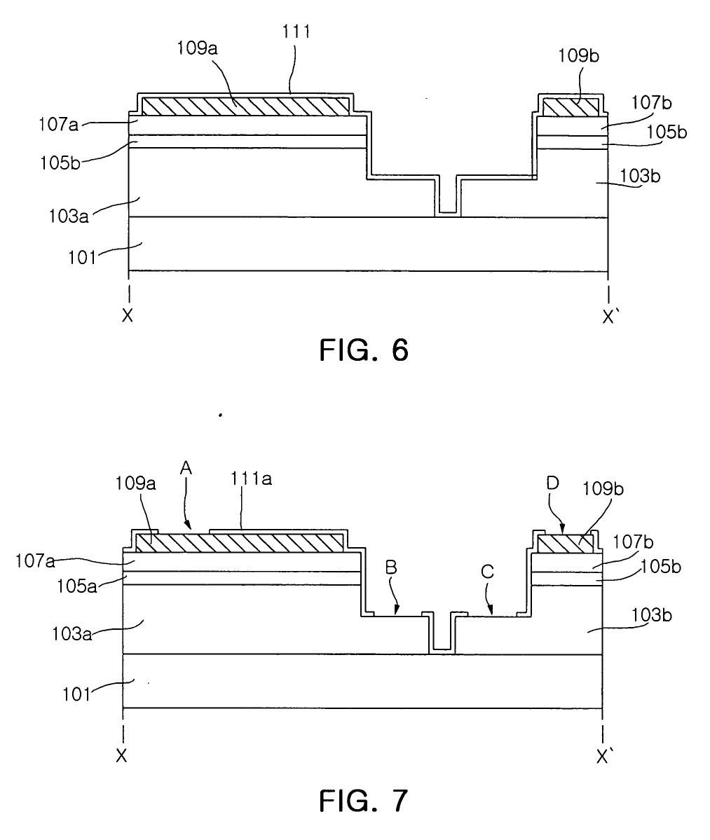

FIG. 2a is a cross-sectional view illustrating a gallium nitride-based light emitting device 200 according to one embodiment of the invention, FIG. 2b is an equivalent circuit diagram of FIG. 2, and FIG. 2b is a plan view schematically illustrating the gallium nitride-based light emitting device shown in FIG. 2a. FIG. 2a shows the cross section taken along line X-X′ of FIG. 2c.

First, referring to FIGS. 2a to 2c, a main LED 150 and an ESD protecting LED 160 are formed on two regions separated from each other by a device separating region 140 on a single substrate 101. The main LED 150 is formed for the purpose of light emission, and the ESD protecting LED 160 is formed for the purpose of protecting the light emitting device from a reverse ESD voltage applied to the main LED 150. The main LED 150 and the ESD protecting LED 160 are separated from each other by the device isolation region 140.

The main LED 150 comprises a first mesa structure including a first n-type GaN-based clad layer 103a, a first active layer 105a and a first p-type GaN-based clad layer 107a sequentially formed on the substrate 101. A transparent electrode 109a and a first p-side electrode 110 are formed on the first p-type GaN-based clad layer 107a. A portion of the n-type GaN-based clad layer 103a is exposed by mesa etching, and a first n-side electrode 112 is formed on the exposed portion of the first n-type GaN-based clad layer 103a.

The ESD protecting LED 160 comprises a second mesa structure including a second n-type GaN-based clad layer 103b, a second active layer 105b and a second p-type GaN-based clad layer 107b sequentially formed on the substrate 101. Additionally, a transparent electrode 109b and a second p-side electrode 116 are sequentially formed on the second p-type GaN-based clad layer 107b, and a second n-side electrode 114 is formed on an exposed portion of the second n-type GaN-based clad layer 103b. In the present embodiment, the transparent electrodes 109a and 109b are formed on the first and second p-type GaN-based clad layers 107a and 107b. Alternatively, the transparent electrode can be formed only on the first p-type GaN-based clad layer 107a without being formed on the second p-type GaN-based clad layer 107b. This is because the main purpose of the ESD protecting LED 160 is to protect against ESD rather than to enhance light emission.

The first p-side electrode 110 of the main LED 150 is electrically connected to the second n-side electrode 114 of the ESD protecting LED 160 via a first wire 120, and the first n-side electrode 112 is electrically connected to the second p-side electrode 116 via a second wire 130. As described below, the first wire 120 can be made of the same material as that of the second n-side electrode 114, and in particular, be formed simultaneously with formation of the second n-side electrode 114. The second wire 130 can be formed by wire bonding. As such, the p-side electrodes 110 and 116 are connected to the n-side electrodes 114 and 112, respectively, thereby providing a light emitting device having two LEDs 150 and 160 connected in parallel as shown in FIG. 2b.

Referring to FIG. 2b, in order to prevent damage of the main LED 150 by the reverse ESD voltage instantaneously applied thereto, the ESD protecting LED 160 is connected in parallel to the main LED 150, and in particular, with biasing polarity connected in reverse with respect to the main LED 150. As such, when the main LED 150 is connected to the ESD protecting LED 150, the reverse ESD voltage applied to the main LED 150 turns on the ESD protecting LED 160. As a result, most of current abnormal to the main LED 150 flows via the ESD protecting LED 160.

When normal forward voltage is applied to two terminals V₁ and V₂ of the main LED 150, most of the current flows through a p-n junction of the main LED 150, and become forward current for light emission. However, when an instantaneous reverse voltage, such as the reverse ESD voltage, is applied to the main LED 150, this reverse voltage is discharged through the ESD protecting LED 160, so that most of current flows through the ESD protecting LED 160 instead of the main LED 150. As a result, the main LED 150 is protected from the reverse ESD voltage, and negative influence on the main LED 150 is minimized.

Although not shown in FIG. 2a, a passivation layer for opening the electrodes 110, 112, 114, and 116 may be formed over the overall surface of the resultant except for the p-side electrodes 110 and 116 and the n-side electrodes 112 and 114. The passivation layer is composed of a dielectric layer, such as SiO₂, and acts to protect the LEDs. In particular, as shown in FIG. 2c, when the first p-side electrode 110 is directly connected to the second n-side electrode 114 via the first wire 120 formed of a wire layer, the passivation layer can prevent the first wire 120 from being shorted to the transparent electrode 109a or the first n-type GaN-based clad layer 103a below the first wire 120.

Referring to FIGS. 2a and 2c, the p-side electrodes 110 and 116, and the n-side electrodes 114 and 112 can be composed of the same material, for example, a Cr/Au layer. Thus, these electrodes 110, 112, 114 and 116 can be formed at the same time by metal deposition. Moreover, as shown in FIG. 2c, the first wire 120 connecting the first p-side electrode 110 to the second n-side electrode 114 is formed as the wire layer. The first wire 120 formed as the wire layer can be made of the same material as that (Cr/Au layer) of the electrodes 110, 112, 114 and 116, and can be formed simultaneously with the electrodes. On the contrary, the second wire 130 connecting the first n-side electrode 112 to the second p-side electrode 116 can be formed by a subsequent wire bonding process.

In this manner, the first wire 120 composed of the wire layer is formed during formation of the electrodes, reducing the number of wire-bonding portions formed by the subsequent process while enabling detection of leakage current of the main LED in a chip stage prior to formation of the wire bonding. That is, since the first wire 120 is connected as the wire layer in the chip stage prior to formation of the wire bonding, only the second wire 130 need be connected by wire bonding. Additionally, in order to detect current leakage of the main LED 150 formed for the purpose of light emission, at least one of the first and second wires 120 and 130 must be disconnected. In the chip stage prior to formation of the wire bonding, since only the first wire 120 is connected as the wire layer, it is possible to sufficiently detect current leakage of the main LED 150.

Furthermore, as shown in FIGS. 2a and 2c, the ESD protecting LED 160 is smaller than the main LED 150. Preferably, the size of the ESD protecting LED 160 is ⅙ to ½ the size of the main LED 150. In order to achieve desired light emitting efficiency, the main LED 150 is formed larger than the ESD protecting LED 160. As the size of the ESD protecting LED 160 is increased, resistance to the reverse ESD voltage can be enhanced. However, if the size of the ESD protecting GaN-based LED is significantly increased, the overall size of the device is also increased, thereby complicating a manufacturing process. If the size of the ESD protecting GaN-based LED is significantly lowered, it is difficult to ensure a sufficient resistance to the reverse ESD voltage.

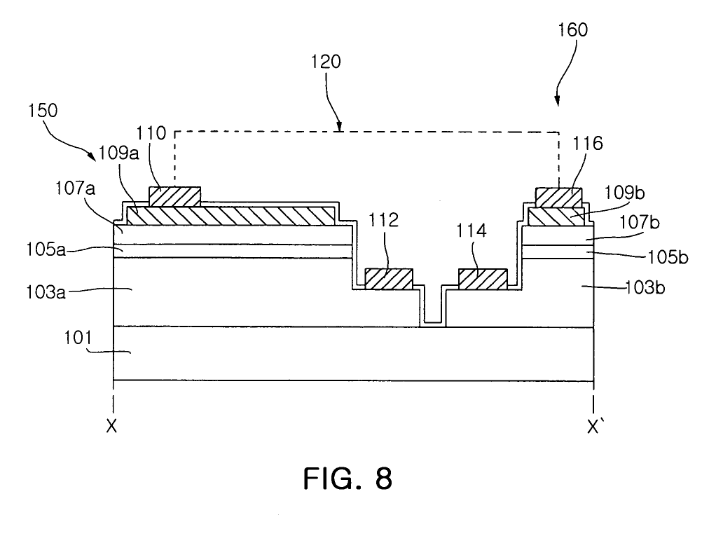

A method for manufacturing a gallium nitride light emitting device of the invention will now be described. FIGS. 3 to 8 are cross-sectional views illustrating a method for manufacturing a gallium nitride-based light emitting device according to one embodiment.

First, referring to FIG. 3, an n-type GaN-based clad layer 103, an active layer 105 and a p-type GaN-based clad layer 107 are sequentially formed on a substrate 101, such as a sapphire substrate or the like. The active layer may have a stacked structure of, for example, GaN layer and InGaN layer, and constitute a multi-quantum well structure. Moreover, a buffer layer (not shown) may be formed between the substrate 101 and the n-type GaN-based clad layer 103 to relieve lattice mismatch between the substrate and the GaN-based semiconductor Then, some portions of the p-type GaN-based clad layer 107, active layer 105 and n-type GaN-based clad layer 103 are selectively etched in some region of the stack (mesa etching). Thus, a structure as shown in FIG. 4 is obtained, and a portion of the n-type GaN-based clad layer 103 is exposed. At this time, two protrusions including the active layer 105 and the p-type GaN-based clad layer 107 are formed on an unexposed portion of the n-type GaN-based clad layer 103.

Then, as shown in FIG. 5, two separated mesa structures are formed by completely etching the exposed portion of the n-type GaN-based clad layer 103. A mesa structure (first mesa structure) shown at left in FIG. 5 is a stack for forming the main LED 150 (see FIG. 2a), and another mesa structure (second mesa structure) shown at right in FIG. 5 is a stack for forming the ESD protecting LED 160 (see FIG. 2a).

Next, as shown in FIG. 6, transparent electrodes 109a and 109b are formed on the p-type GaN-based clad layers 107a and 107b of the first and second mesa structures, respectively. Alternatively, a transparent electrode may be formed only on the p-type GaN-based clad layer 107a of the first mesa structure. Then, a passivation layer 111 is formed over the entire surface of the mesa structure comprising the transparent electrodes 109a and 109b. Next, as shown in FIG. 7, the passivation layer 111 is selectively etched so as to open regions where p-side electrodes and n-side electrodes will be formed. Accordingly, a passivation pattern 111a for exposing regions A, B, C and D for the electrodes is formed.

Finally, as shown in FIG. 8, p-side electrodes 110 and 116, and n-side electrodes 112 and 114 are formed on the region exposed through the passivation pattern 111a. The p-side electrodes 110 and 116 and the n-side electrodes 112 and 114 can be concurrently formed using Cr/Au layers. At this time, while forming the p-side electrodes 110 and 116 and the n-side electrodes 112 and 114, a wire layer 120 (see FIG. 2c) for connecting the p-side electrode 110 formed on the main LED 150 to the n-side electrode 114 formed on the ESD protecting LED 160 can be formed. The electrical connection via the wire layer 120 is schematically illustrated by a dotted line. As a result, the light emitting device comprising the main LED 150 and the ESD protecting LED 160 is manufactured. The n-side electrode 112 formed on the main LED is electrically connected to the p-side electrode 116 formed on the ESD protecting LED by a subsequent wire bonding process.

### EXAMPLE

In order to verify ESD characteristics of a gallium nitride-based light emitting device according to the invention, tests were conducted for detecting breakdown voltages against forward and reverse ESD. In these tests, the gallium nitride light emitting device of the inventive example includes a main LED having a size of 610 μm×200 μm, and an ESD protecting LED connected in parallel to the main LED and having a size of 100 μm×200 μm. Cr/Au metal layers are used for n-side and p-side electrodes, and an ITO layer is used for transparent layers. On the contrary, the GaN-based light emitting device of the conventional example does not have the ESD protecting LED, and comprises one GaN-based LED. The GaN-based LED of the conventional GaN-based light emitting device has the same size as that of the GaN-based light emitting device of the invention.

As results of detecting the ESD characteristics of the GaN-based light emitting devices of the inventive and conventional examples, breakdown voltages against forward and reverse ESD were obtained as shown in the following Table 1.

TABLE 1

| | Breakdown voltaget | Breakdown voltage |
|---|---|---|
| | agains forward ESD | against reverse ESD |
| Conventional example | 2.0 kV | 0.12 kV |
| Inventive example | 2.0 kV | 2.0 kV |

As shown in Table 1, the breakdown voltage against reverse ESD of the GaN-based light emitting device of the inventive example is higher than 8 times that of the conventional example. As such, according to the invention, the ESD protecting LED is connected in parallel to the main LED in the opposite direction, thereby enhancing reverse ESD protection capabilities.

As apparent from the above description, the ESD protecting LED and the main LED are formed on a single substrate while being connected in parallel in opposite directions, thereby providing a high breakdown voltage against reverse ESD, and effectively protecting the light emitting device from the reverse ESD. Moreover, since the existing material for the electrodes of the GaN-based LED is used, the process is greatly simplified. Additionally, during the step of forming the n-side electrode, the wire layer may be formed for connecting the p-side electrode of the main LED to the n-side electrode of the ESD protecting LED, thereby reducing the number of wire-bonding portions while enabling detection of leakage current of the main LED prior to wire bonding.

It should be understood that the embodiments and the accompanying drawings have been described for illustrative purposes and the present invention is limited only by the following claims. Further, those skilled in the art will appreciate that various modifications, additions and substitutions are allowed without departing from the scope and spirit of the invention as set forth in the accompanying claims.

What is claimed is:

1. A gallium nitride-based light emitting device, comprising:
a substrate;
a main GaN-based LED including a first p-side electrode and a first n-side electrode, the main GaN-based LED formed in a first region on the substrate; and
an ESD protecting GaN-based LED including a second p-side electrode and a second n-side electrode, the ESD protecting GaN-based LED formed in a second region on the substrate,
wherein the first region is separated from the second region by a device isolation region, and the first p-side and n-side electrodes are electrically connected to the second n-side and p-side electrodes, respectively.

2. The light emitting device as set forth in claim 1, wherein the main GaN-based LED comprises:
a first mesa structure including a first n-type GaN-based clad layer, a first active layer and a first p-type GaN-based clad layer sequentially formed on the substrate, the first n-type GaN-based clad layer having a partially exposed region;
the first p-side electrode formed on the first p-type GaN-based clad layer; and
the first n-side electrode formed on the exposed region of the first n-type GaN-based clad layer.

3. The light emitting device as set forth in claim 2, wherein the ESD protecting GaN-based LED comprises:
a second mesa structure including a second n-type GaN-based clad layer, a second active layer and a second p-type GaN-based clad layer sequentially formed on the substrate, the second n-type GaN-based clad layer having a partially exposed region;
the second p-side electrode formed on the second p-type GaN-based clad layer; and
the second n-side electrode formed on the exposed region of the second n-type GaN-based clad layer.

4. The light emitting device as set forth in claim 3, wherein the main GaN-based LED further comprises a transparent electrode between the first p-type GaN-based clad layer and the first p-side electrode.

5. The light emitting device as set forth in claim 4, wherein the ESD protecting GaN-based LED further comprises a transparent electrode between the second p-type GaN-based clad layer and the second p-side electrode.

6. The light emitting device as set forth in claim 4, further comprising:
a passivation layer formed on the first and second mesa structures and the transparent electrode to open the first and second p-side electrodes and the first and second n-side electrodes.

7. The light emitting device as set forth in claim 3, further comprising:
a wire layer for connecting the first p-side electrode to the second n-side electrode.

8. The light emitting device as set forth in claim 3, wherein the first and second p-side electrodes and the first and second n-side electrodes are made of the same material.

9. The light emitting device as set forth in claim 8, wherein the first and second p-side electrodes and the first and second n-side electrodes comprise a Cr/Au layer.

10. The light emitting device as set forth in claim 7, wherein the wire layer, the first and second p-side electrodes and the first and second n-side electrodes are made of the same material.

11. The light emitting device as set forth in claim 1, wherein the size of the ESD protecting GaN-based LED is ⅙ to ½ the size of the main GaN-based LED.

12. A method for manufacturing a gallium nitride-based light emitting device, comprising the steps of:
sequentially forming an n-type GaN-based clad layer, an active layer and a p-type GaN-based clad layer on a substrate;
exposing a portion of the n-type GaN-based clad layer by etching some portions of the p-type GaN-based clad layer, active layer and n-type GaN-based clad layer;
forming a first mesa structure and a second mesa structure separated from each other by partially etching the exposed portion of the n-type GaN-based clad layer;
forming n-side electrodes on the exposed n-type GaN-based clad layer of the first and second mesa structures, respectively; and
forming p-side electrodes on the p-type GaN-based clad layer of the first and second mesa structures, respectively.

13. The method as set forth in claim 12, wherein the size of the second mesa structure is ⅙ to ½ the size of the main GaN-based LED.

14. The method as set forth in claim 12, further comprising:
forming a transparent electrode on the p-type GaN-based clad layer of the first mesa structure before forming the n-side electrodes.

15. The method as set forth in claim 14, further comprising:
forming a transparent electrode on the p-type GaN-based clad layer of the second mesa structure when forming the transparent electrode on the p-type GaN-based clad layer of the first mesa structure.

16. The method as set forth in claim 14, further comprising:
forming a passivation layer on the first and second mesa structures and the transparent electrode between the steps of forming the n-side electrodes and the transparent electrode.

17. The method as set forth in claim 16, further comprising:
forming a wire layer for connecting the p-side electrode of the first mesa structure to the n-side electrode of the second mesa structure when forming the n-side electrodes.
